(19) United States
(12) Patent Application Publication
(10) Pub. No.: US 2024/0168054 A1
(43) Pub. Date: May 23, 2024

(54) IC INSPECTION SOCKET

(71) Applicant: YOKOWO CO., LTD., Kita-ku, Tokyo (JP)

(72) Inventors: Kohei AMADA, Tomioka-shi, Gunma (JP); Yuki MATSUI, Tomioka-shi, Gunma (JP)

(73) Assignee: YOKOWO CO., LTD., Kita-ku, Tokyo (JP)

(21) Appl. No.: 17/773,036

(22) PCT Filed: Aug. 11, 2020
(86) PCT No.: PCT/JP2020/030591

§ 371 Date: Apr. 29, 2022

(30) Foreign Application Priority Data
Oct. 31, 2019 (JP) 2019-198311

(51) Int. Cl. G01R 1/04; H01R 13/512; H01R 13/631

(52) U.S. Cl. CPC G01R 1/0433; H01R 13/512; H01R 13/631

(57) ABSTRACT

An IC inspection socket includes: a pin block including a contact probe array; a guide plate configured to guide an IC package to be inspected to the contact probe array; and a cover including an engaging portion to be engaged with the pin block, and configured to hold the guide plate by an engagement of the engaging portion. The pin block includes a support portion configured to detachably support the guide plate, and an engaged portion with which the engaging portion is engaged during a sliding movement of the cover on the guide plate supported by the support portion.

### TECHNICAL FIELD

The present invention relates to an IC (Integrated Circuit) inspection socket.

### BACKGROUND ART

An IC inspection socket is used for an inspection of an IC package (see, for example, Patent Literature 1).

An IC inspection socket includes a pin block in which a plurality of contact probes respectively corresponding to electrode terminals of an IC are erected, and a guide member provided above the pin block. When the IC package to be inspected is inserted into the guide member in a posture in which the electrode terminals face downward, the IC package is guided onto the contact probes in a predetermined posture. By appropriately pressing the IC package from an upper side to a lower side, the electrode terminals of the IC package come into contact with the contact probes, and thus an electric conduction path for inspection is ensured.

A guide member of a conventional IC inspection socket is fixed to a pin block with a screw as disclosed in Patent Literature 2.

### CITATION LIST

### Patent Literature

Patent Literature 1: JP-A-2016-207511

Patent Literature 2: JP-A-2004-325305

### SUMMARY OF INVENTION

### Technical Problem

There is types of the IC packages to be inspected having the same arrangement of the electrode terminals but having different outer shapes. When IC packages having the same arrangement of electrode terminals but different outer shapes are inspected, the IC inspection socket has the following problem. Since the arrangements of the electrode terminals are the same, it is desired to share the pin block. On the other hand, since the outer shapes of the IC packages are different, it is necessary to replace the guide member. However, there is a problem that the replacement work is troublesome. There is a problem that, in order to replace the guide member, a screw for fixing the guide member to the pin block is removed, the guide member is taken out, and then the guide member to be replaced is fixed to the pin block by the screw, which is troublesome.

An IC package is required to be further reduced in size and improved in function. Many electrode terminals tend to be arranged at a high density in a smaller package size. Also in the IC inspection socket, it is necessary to increase an arrangement density of the contact probes in order to match the contact probes to the electrode terminals arranged at a high density. However, as a result, in the IC inspection socket, the screw for fixing the guide member to the pin block is minimized, and it takes much time and effort to replace the guide member. In addition, in the IC inspection socket, it is becoming difficult to secure a space for fitting a screw.

An object of the present invention is to facilitate an operation of inspecting an IC package having a different package outer shape by an IC inspection socket.

### Solution to Problem

According to an aspect of the present invention, there is provided an IC (Integrated Circuit) inspection socket including: a pin block including a contact probe array; a guide plate configured to guide an IC package to be inspected to the contact probe array; and a cover including an engaging portion configured to engage with the pin block, and is configured to hold the guide plate by an engagement of the engaging portion, in which the pin block includes a support portion configured to detachably support the guide plate, and an engaged portion with which the engaging portion is engaged during a sliding movement of the cover on the guide plate supported by the support portion.

According to the aspect of the present invention, the cover is not fixed to the pin block by a screw, and the guide plate can be removed only by sliding the cover. Therefore, when an IC package having a different package outer shape is inspected, it is easy to replace the guide plate.

### BRIEF DESCRIPTION OF DRAWINGS

FIG. 1 is an external view illustrating a configuration example of an IC inspection socket.

FIG. 2 is a top view illustrating a configuration example of a socket body.

FIG. 3 is a vertical cross-sectional view of an III-III cross section of FIG. 2 as viewed from a negative side in a Y-axis direction.

FIG. 4 is a top view illustrating a configuration example of a pin block.

FIG. 5 is a top view illustrating a configuration example of a guide plate.

FIG. 6 is a top view illustrating a configuration example of a cover.

FIG. 7 is a bottom view illustrating a configuration example of the cover.

FIG. 8 is a longitudinal sectional view taken along a line VIII-VIII of FIGS. 6 and 7.

FIG. 9 is a view for illustrating an assembly procedure of the socket body (part 1).

FIG. 10 is a view for illustrating the assembly procedure of the socket body (part 2).

### DESCRIPTION OF EMBODIMENTS

Examples of preferred embodiments of the present invention will be described. However, modes to which the present invention can be applied are not limited to the following embodiments. Three orthogonal axes for indicating common directions in the drawings are illustrated. The three orthogonal axes are right-handed axes with a Z-axis positive direction as an upward direction.

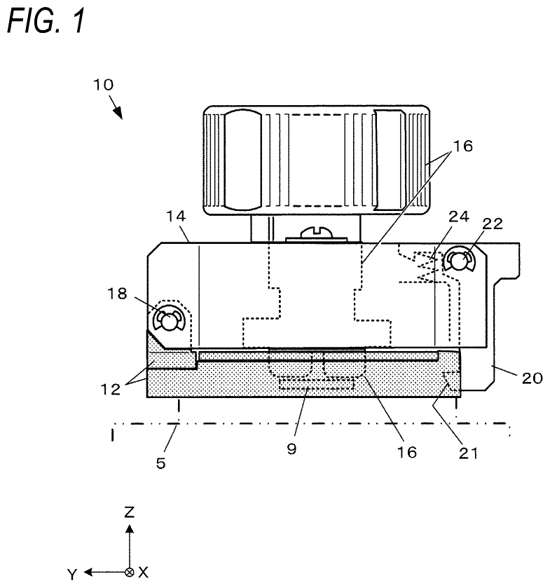

FIG. 1 is an external view illustrating a configuration example of an IC inspection socket 10 of the present embodiment.

The IC inspection socket 10 includes a lid body 14 and a pressing mechanism 16 above a socket body 12.

The socket body 12 is attached to an inspection device 5.

The lid body 14 is swingably supported by a lid body swing shaft 18 extending along an X-axis direction, and supports the pressing mechanism 16 above the socket body 12.

The pressing mechanism 16 applies a load downward to an IC package 9 to be inspected, which is placed in the socket body 12.

A hook 20 is provided on a negative side of the lid body 14 in a Y-axis direction (rightward direction on paper in FIG. 1), which is a side opposite to a side on which the lid body swing shaft 18 is provided. The hook 20 is swingably supported by a hook swing shaft 22 extending along the X-axis direction, and is biased at the hook swing shaft 22 by a coil spring 24 in a clockwise direction when viewed from a negative side in the X-axis direction.

When an engagement pawl 21 of the hook 20 is engaged with the socket body 12, the hook 20 maintains a state where the lid body 14 covers an upper side of the socket body 12. By removing the hook 20, the inside of the socket body 12 is exposed when the lid body 14 is swung, and the IC package 9 to be inspected can be taken in and out.

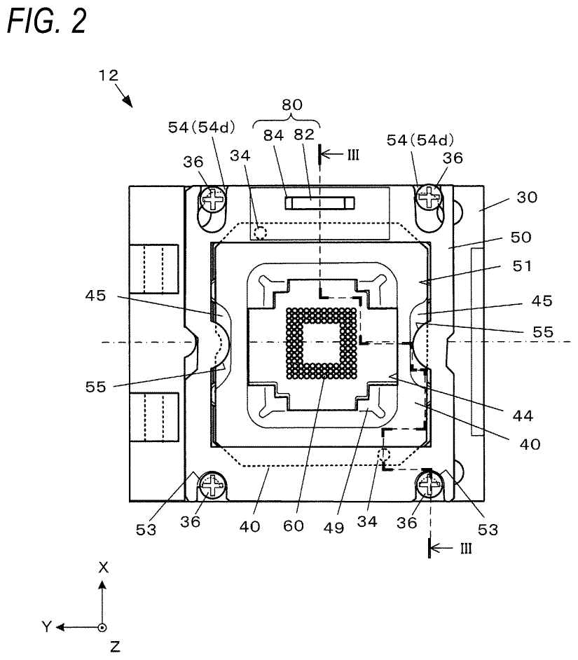

FIG. 2 is a top view illustrating a configuration example of the socket body 12.

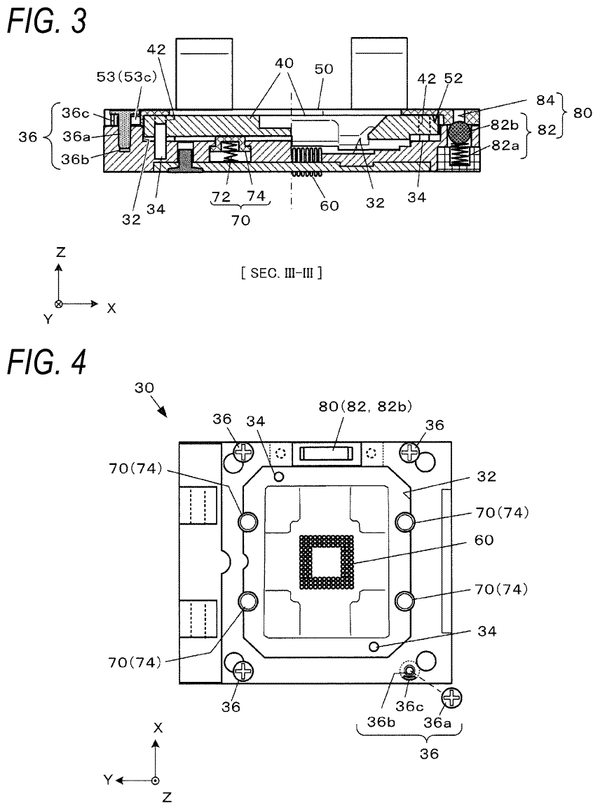

FIG. 3 is a vertical cross-sectional view of the III-III cross section of FIG. 2 as viewed from a negative side in the Y-axis direction.

The socket body 12 includes a pin block 30, a guide plate 40, and a cover 50.

FIG. 4 is a top view illustrating a configuration example of the pin block 30.

The pin block 30 serves as a base body of the socket body 12. The pin block 30 includes an accommodation recess 32 including a bottom surface extending along an XY plane, and a contact probe array 60 is provided in a central portion of the accommodation recess 32. The pin block 30 includes an elastic restriction portion 82 that constitutes a displacement restriction portion 80.

The contact probe array 60 is configured by arranging a plurality of contact probes along the XY plane so as to correspond to an arrangement of electrode terminals of the IC package 9 to be inspected. Each contact probe of the contact probe array 60 is erected in the accommodation recess 32 such that a longitudinal direction thereof is along the Z-axis direction.

An outer shape of the accommodation recess 32 in a top view is set to a shape similar to or substantially similar to an outer shape of the guide plate 40 in a top view. The guide plate 40 can be placed in the accommodation recess 32 in a posture substantially parallel to the XY plane, and can be fitted into the recess from above. The accommodation recess 32 functions as a guide accommodation mechanism that guides a lower portion (a portion on a negative side in the Z-axis direction) of the guide plate 40 to a predetermined position and accommodates the lower portion.

The pin block 30 includes a plurality of support portions 70 at both end portions of the accommodation recess 32 in the Y-axis direction. The support portion 70 includes a spring 72 installed inside the pin block 30, and a spring cap 74 that covers an upper portion of the spring 72 and is biased upward by the spring 72 (see FIG. 3). A head portion (upper end portion) of the spring cap 74 protrudes from a bottom surface of the accommodation recess 32. The head portion of the spring cap 74 abuts against a lower surface of the guide plate 40, such that the support portion 70 elastically supports the guide plate 40.

Parallel pins 34 are erected on the bottom surface of the accommodation recess 32 in parallel with the Z-axis direction. In the present embodiment, two parallel pins 34 are erected. The guide plate 40 is provided with insertion holes 42 through which a the parallel pins 34 are inserted. When the parallel pins 34 are inserted into the insertion holes 42 and the accommodation recess 32 functions as the guide accommodation mechanism, the guide plate 40 supported by the support portion 70 is elastically supported in a manner of being movable up and down along the Z-axis direction. Accordingly, the guide plate 40 is elastically supported in a manner of being able to approach and separate from the contact probe array 60.

An upper surface of the pin block 30 corresponding to an outer edge of the accommodation recess 32 is provided with engaged portions 36 with which the cover 50 is to be slidably engaged. Specifically, the engaged portions 36 each include a screw 36a, a screw hole 36b provided on the upper surface of the pin block 30, and a projection portion 36c protruding from the upper surface of the pin block 30 at an outer peripheral portion of the screw hole 36b.

The screw 36a is a small screw having a flat head and a seat surface that is substantially perpendicular to a threaded portion. The screw 36a may be a tapping screw. In this case, it is not necessary to form a female screw in the screw hole 36b.

When the screw 36a is screwed into the screw hole 36b, the seat surface abuts against an upper surface of the projection portion 36c, and thus a height of the screw 36a is determined.

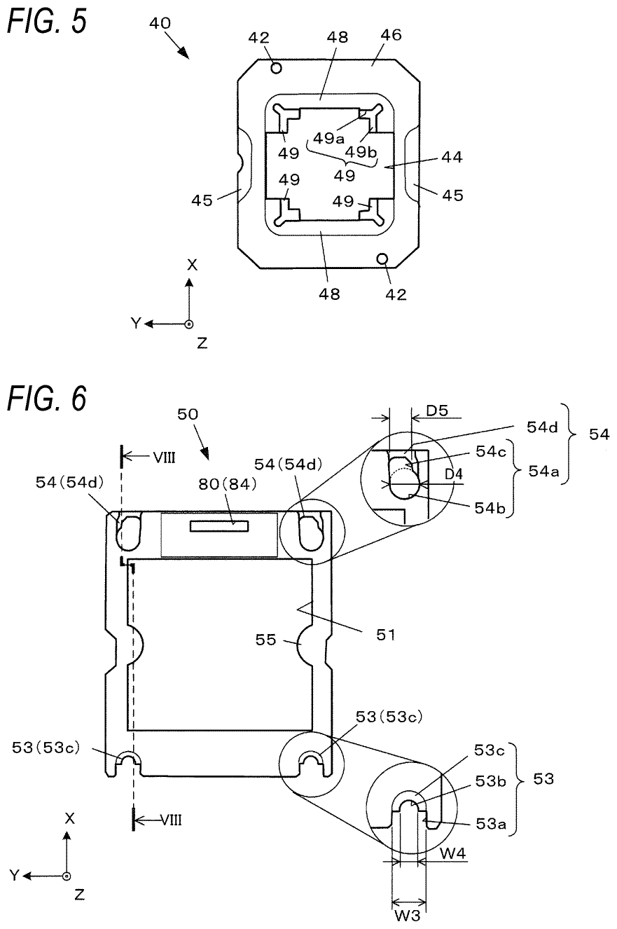

FIG. 5 is a top view illustrating a configuration example of the guide plate 40.

The guide plate 40 is a plate-shaped guide member that guides the IC package 9 to be inspected to the contact probe array 60 of the pin block 30. The guide plate 40 may also be referred to as a floating plate since the guide plate 40 is elastically supported by the support portion 70.

The guide plate 40 includes an outer edge portion 46, a window portion 44, guide surfaces 48 each inclined from an upper end surface of the outer edge portion 46 toward an edge of the window portion 44, and shelf-shaped positioning portions 49.

The window portion 44 is a space provided in a central portion of the guide plate 40 in a top view in order to expose the contact probe array 60 of the pin block 30 in the top view.

The positioning portions 49 each include a standing surface 49a extending along the Z axis and falling downward from the lower end of the guide surface 48, and a shelf-shaped portion 49b extending along the XY plane toward the inside a window portion of the window portion 44.

The IC package 9 to be inspected is inserted into the window portion 44 of the guide plate 40 from above in a posture in which the electrode terminal faces downward. The inserted IC package 9 to be inspected slides down while substantially maintaining the posture at the time of insertion with an outer edge portion abutting against the guide surface 48. Then, the IC package 9 to be inspected is stopped in a state where the outer edge is fitted into the standing surface 49a of the positioning portion 49 and the four corners are placed on the shelf-shaped portion 49b. When viewed from above, the IC package 9 to be inspected in this state is positioned such that the contact probes of the corresponding contact probe array 60 are positioned immediately below the electrode terminals of the bottom surface one by one.

FIG. 6 is a top view illustrating a configuration example of the cover 50.

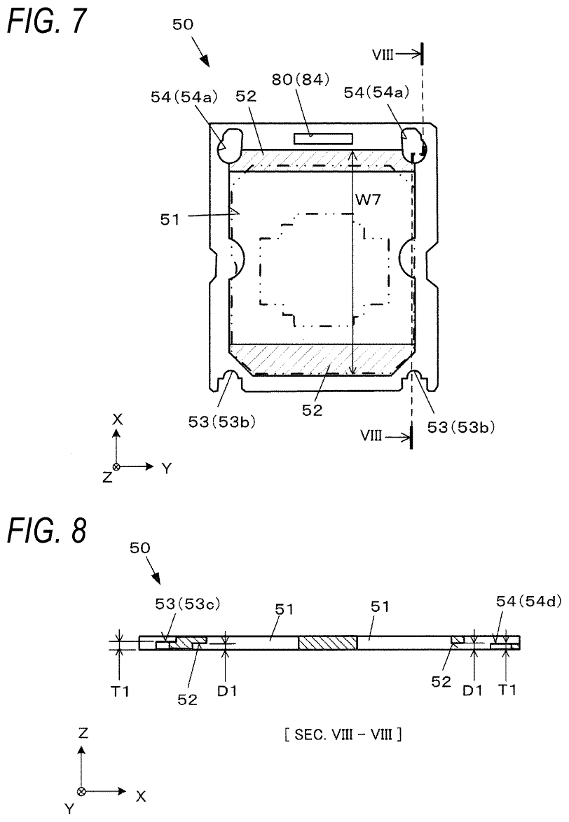

FIG. 7 is a bottom view illustrating a configuration example of the cover 50.

FIG. 8 is a longitudinal sectional view taken along a line VIII-VIII in FIGS. 6 and 7.

The cover 50 is a member that holds the guide plate 40 from above in a state where the guide plate 40 is placed on and elastically supported by the support portion 70 in the accommodation recess 32. Specifically, the cover 50 is a member including, at a central portion of a plate-shaped member in a top view, a window portion 51 that is larger than the window portion 44 of the guide plate 40 and smaller than the outer shape of the guide plate 40 in a top view. The cover 50 can be said to be a frame body with a small thickness (thin in the Z direction) and whose central portion is provided with an opening portion.

A lower surface of the cover 50 is provided with facing recesses 52 in a recessed manner, that face and come into contact with an upper surface of the guide plate 40. The facing recesses 52 are portions indicated by hatching in FIG. 7, and are provided on a side portion on an X-axis positive side and a side portion on an X-axis negative side of the window portion 51 on the lower surface of the cover 50.

A depth D1 (recess dimension: see FIG. 8) of a step of each of the facing recesses 52 is set to be equal to or slightly larger than a dimension by which an upper portion of the guide plate 40 elastically supported by the support portion 70 protrudes upward from the upper surface of the pin block 30.

A width of each of the facing recesses 52 in the Y-axis direction is set to be slightly larger than a width of the guide plate 40 (two-dot chain line in FIG. 7) in the Y-axis direction.

A width of each of the facing recesses 52 in the X-axis direction is set to be slightly larger than the sum of a width of the guide plate 40 in the X-axis direction and a sliding distance of the cover 50, which will be described later, by a sliding operation.

The cover 50 includes first fixing portions 53 at end portions on the X-axis negative side (a lower side on paper in FIGS. 6 and 7), and second fixing portions 54 at end portions on the X-axis positive side (an upper side on paper in FIGS. 6 and 7).

The first fixing portions 53 are provided on each respectively at top-view corners of the cover 50 on the X-axis negative side. The first fixing portions 53 each include an introduction opening portion 53a, a narrow portion 53b, and a first engaging portion 53c.

The introduction opening portion 53a is a notch that opens in a side surface of the cover 50 on the X-axis negative side. An opening width W3 of the introduction opening portion 53a in the Y-axis direction in a top view is slightly larger than an outer shape of the head portion of the screw 36a.

The narrow portion 53b is a portion whose opening width is smaller than that of the introduction opening portion 53a on the X-axis direction positive side (the back side of the notch) of the first fixing portion 53. An opening width W4 of the narrow portion 53b in the Y-axis direction in a top view is smaller than the outer shape of the head portion of the screw 36a and is slightly larger than an outer shape of the threaded portion of the screw 36a.

The first engaging portion 53c is a portion that is one step lower than the upper surface of the cover 50 and is provided around the narrow portion 53b, in other words, a portion that is partially thin. A thickness TI (see FIG. 8) of the first engaging portion 53c is set to be slightly smaller than the height of the projection portion 36c of the pin block 30. The height of the projection portion 36c of the pin block 30 is larger than the thickness of the first engaging portion 53c. The height of the projection portion 36c of the pin block 30 is smaller than a thickness of the cover 50.

The second fixing portions 54 are provided one each respectively at top-view corners of the cover 50 on the X-axis positive side. The second fixing portions 54 each include a through opening portion 54a and a second engaging portion 54d.

The through opening portion 54a is a through hole penetrating through the cover 50 in a vertical direction, and includes an insertion portion 54b and a narrow portion 54c. When the through opening portion 54a is viewed from above, the through opening portion 54a has a shape in which the narrow portion 54c communicates with and is integrated with an end portion of the circular insertion portion 54b on the X-axis positive side.

An opening diameter D4 (a width in the Y-axis direction and a width in the X-axis direction) of the insertion portion 54b is slightly larger than the outer shape of the head portion of the screw 36a. An opening width D5 of the narrow portion 54c in the Y-axis direction in a top view is smaller than the outer shape of the head portion of the screw 36a, and is slightly larger than the outer shape of the threaded portion of the screw 36a.

The second engaging portion 54d is a portion that is one step lower than the upper surface of the cover 50 and is provided around the narrow portion 54c, in other words, a portion that is partially thin. A thickness of the second engaging portion 54d is set to be equal to the thickness TI (see FIG. 8) of the first engaging portion 53c, and is set to be slightly smaller than the height of the projection portion 36c of the pin block 30. The height of the projection portion 36c of the pin block 30 is larger than the thickness of the second engaging portion 54d. The height of the projection portion 36c of the pin block 30 is smaller than the thickness of the cover 50.

The displacement restriction portion 80 includes an elastic restriction portion 82 (see FIG. 3) that elastically protrudes upward from the upper surface of the pin block 30, and a through hole 84 (see FIG. 6) that is provided in the cover 50 and penetrates through the cover 50 in the vertical direction.

The elastic restriction portion 82 includes a biased member 82b biased upward by a spring 82a inside the pin block 30 on the X-axis positive side (for example, the biased member 82b is disposed by tilting a metal cylindrical member along the Y-axis direction).

When the cover 50 is assembled to the pin block 30, the through hole 84 is positioned above the elastic restriction portion 82. The portion of the elastic restriction portion 82, which protrudes from the upper surface of the pin block 30, is fitted into and engaged with the through hole 84 (see FIG. 3), such that a displacement of the cover 50 in the X-axis direction is restricted.

Next, an assembly procedure of the socket body 12 will be described.

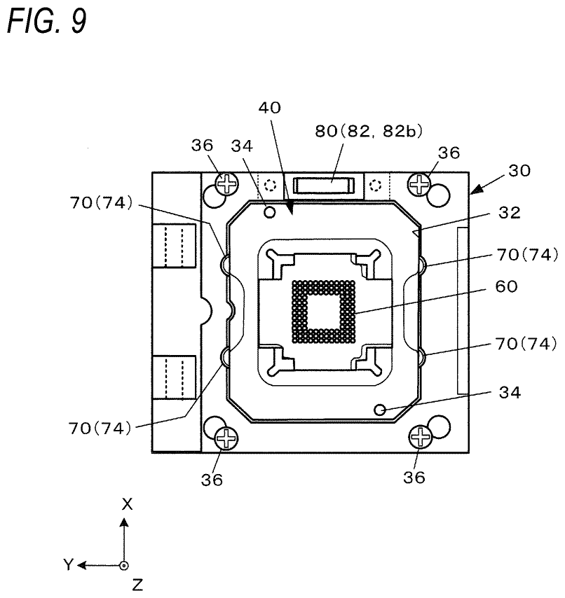

First, as shown in FIG. 9, an operator fits the guide plate 40 into the accommodation recess 32 of the pin block 30 from above. At the time of fitting, the parallel pin 34 is inserted into the insertion hole 42. The lower surface of the guide plate 40 abuts against an upper surface of the support portion 70, and the guide plate 40 is elastically supported by the support portion 70. The lower surface (a side surface on a Z-axis negative side) of the guide plate 40 enters inside the accommodation recess 32, and the guide plate 40 does not move along the XY plane relative to the pin block 30. In this state, the upper surface (a side surface on the Z-axis positive side) of the guide plate 40 does not enter the accommodation recess 32, and protrudes upward from the upper surface of the pin block 30. In this state, the guide plate 40 can be pressed downward (in the Z-axis negative direction) against an elastic support force of the support portion 70.

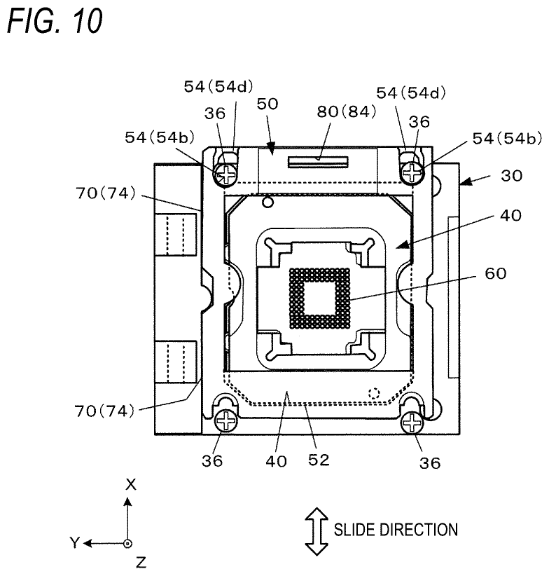

Next, as shown in FIG. 10, the operator covers the guide plate 40 with the cover 50 from above. Specifically, the operator covers the guide plate 40 with the cover 50 such that the engaged portion 36 on the X-axis positive side (upper side on paper in FIG. 10) is inserted into the insertion portion 54b (see FIG. 6) of the second fixing portion 54 in a posture in which the through hole 84 of the cover 50 is on the X-axis positive side.

At this time, the upper surface of the guide plate 40 is accommodated in the window portion 51 and the facing recesses 52 of the cover 50. Specifically, the guide plate 40 is positioned at a relative position indicated by a two-dot chain line in FIG. 7, and is accommodated in the facing recesses 52.

At this stage, the engaged portion 36 on the X-axis negative side (lower side on paper in FIG. 10) does not enter the introduction opening portion 53a of the first fixing portion 53. The through hole 84 of the displacement restriction portion 80 does not reach the upper side of the elastic restriction portion 82. Since the elastic restriction portion 82 is covered with the cover 50 by the operator, the elastic restriction portion 82 is in a state being pressed downward by the lower surface of the cover 50. That is, the through hole 84 and the elastic restriction portion 82 are not engaged with each other, and the displacement restriction portion 80 does not function.

Next, when the operator slides the cover 50 from the X-axis positive side to the X-axis negative side, the state shown in FIG. 2 is obtained. Due to the sliding movement, in the first fixing portion 53 (see FIG. 6) of the cover 50, the threaded portion of the screw 36a on the X-axis negative side (lower side on paper in FIG. 10) is introduced into the narrow portion 53b, and the threaded portion abuts against a back wall of the narrow portion 53b, so that the sliding movement is stopped. In this process, the first engaging portion 53c is fitted into a gap between the seat surface of the screw 36a and the upper surface of the pin block 30. Accordingly, the end portion of the cover 50 on the X-axis negative side is less likely to move in the Z-axis direction (vertical direction).

Further, due to this sliding movement, in the second fixing portion 54 (see FIG. 6) of the cover 50, the threaded portion of the screw 36a on the X-axis positive side is introduced into the narrow portion 54c, and the second engaging portion 54d is fitted into the gap between the seat surface of the screw 36a and the upper surface of the pin block 30. Accordingly, the end portion of the cover 50 on the X-axis positive side is less likely to move in the Z-axis direction (vertical direction).

Further, due to this sliding movement, in the displacement restriction portion 80, the elastic restriction portion 82 reaches a position directly below the through hole 84, and the biased member 82b enters the through hole 84. In this process, the operator obtains a click feeling and knows that the cover 50 has slid to a correct position. Since the biased member 82b enters the through hole 84, the restriction function of the displacement restriction portion 80 is exerted.

A width W7 (see FIG. 7) of the facing recesses 52 in the X-axis direction is set to be larger than a sliding range during the sliding movement so that the guide plate 40 can slide relative to the cover 50 along with the sliding movement. Therefore, the cover 50 can smoothly slide on the guide plate 40 even during the sliding movement.

In addition, the cover 50 slides in a state where bulging portions 55 (see FIG. 6) of the cover 50 respectively enter recesses 45 (see FIG. 5) recessed in an upper surface of the Y-axis positive side end portion and an upper surface of the Y-axis negative side end portion of the guide plate 40. The bulging portions 55 are protruding portions formed in a manner of protruding toward a center of the window portion 51 from an inner surface of the window portion 51 on the Y-axis positive side and an inner surface on the Y-axis negative side. Therefore, the cover 50 can smoothly slide on the guide plate 40 even during the sliding movement.

When the sliding movement is finished, the guide plate 40 is covered with the cover 50 at both end portions in the X-axis direction and both end portions in the Y-axis direction so as not to fall out of the accommodation recess 32 of the pin block 30. Focusing on the fact that the guide plate 40 is elastically supported, the cover 50 does not move the guide plate 40 in the XY plane direction, and determines an upper limit position of the elastic support in the Z-axis direction by the support portion 70.

When the IC inspection socket 10 corresponds to another type of IC package having the same arrangement of the electrode terminals and different package outer shapes, the guide plate 40 for each IC package may be separately prepared.

In a new guide plate prepared separately, the positioning portion 49 has a shape suitable for the outer shape of the corresponding another type of IC package. Specifically, in the new guide plate, the four corner positions, the window portion 44, the guide surface 48, and the like are adapted to another type of IC package.

When a user replaces the guide plate 40, the user takes out the attached guide plate 40 from the pin block 30 by reversely following the above-described assembly procedure. Next, the user attaches another guide plate 40 to the pin block 30 again in the above-described assembly procedure.

It is not necessary to remove or attach a screw like a conventional IC inspection socket. In the first place, the guide plate 40 is not fixed by a screw. A tool is not required, and work is extremely simple. In addition, since the fixing screw can be eliminated, it is also advantageous for downsizing the IC inspection socket.

As described above, according to the IC inspection socket 10 of the present embodiment, the work of inspecting IC packages having different package outer shapes can be facilitated.

Since the support portion 70 elastically supports the guide plate in the vertical direction (Z-axis direction) which is a direction intersecting a direction of the sliding movement of the cover 50, the guide plate 40 can function as a floating plate.

The cover 50 includes the facing recesses 52 that come into contact with the facing surfaces of the guide plate 40 respectively. The facing recess 52 is set to a size that allows the facing recess 52 to slide on the facing surface of the guide plate 40 along the direction of the sliding movement. Therefore, in the assembly or disassembly work, it is not required to continue pushing the guide plate 40 that is elastically supported to protrude upward from the upper surface of the pin block 30 (the sliding surface on which the cover 50 is slid), and excellent workability is provided.

The engaged portion 36 is a shaft body (specifically, the screw 36a) including a head portion, the cover 50 includes the insertion portion 54b through which the shaft body is inserted, and the second engaging portion 54d of the second fixing portion 54 is engaged with a lower surface (a seat surface of the screw) of the head portion of the shaft body. The presence of the insertion portion 54b functions as a guide for adjusting a starting positional relation and a starting posture of a correct attachment of the cover 50, and facilitates the assembly work in an easy-to-understand manner.

The pin block 30 includes the screw hole 36b corresponding to the screw 36a and the projection portion 36c that comes into contact with the lower surface of the head portion of the screw 36a inserted into the screw hole 36b, and the height of the projection portion 36c is larger than the thickness of the first engaging portion 53c and the thickness of the second engaging portion 54d (see FIGS. 6 and 8). When the screw 36a is screwed into the screw hole 36b, the seat surface of the screw abuts against the projection portion 36c, and the screw 36a cannot be screwed further. The projection portion 36c can accurately determine the height from the upper surface of the pin block 30 to the seat surface of the screw.

The pin block 30 includes the displacement restriction portion 80 that restricts the displacement of the cover 50 in the direction of the sliding movement in a state where the first engaging portion 53c and the second engaging portion 54d are engaged with the engaged portion 36, so that detachment of the cover 50 can be prevented.

Although an example of the embodiment has been described, the mode to which the present invention can be applied is not limited to the above embodiment, and the constituent elements can be appropriately added, omitted, or changed.

The disclosure of the present embodiment can be summarized as follows.

According to an aspect of the present disclosure, there is provided an IC inspection socket including: a pin block including a contact probe array; a guide plate configured to guide an IC package to be inspected to the contact probe array; and a cover including an engaging portion configured to engage with the pin block, and is configured to hold the guide plate by engagement of the engaging portion, in which the pin block includes a support portion configured to detachably support the guide plate, and an engaged portion with which the engaging portion is engaged during a sliding movement of the cover on the guide plate supported by the support portion.

According to the present aspect, the cover is not fixed to the pin block by a screw, and the guide plate can be removed only by sliding the cover. Therefore, when an IC package having a different package outer shape is inspected, it is easy to replace the guide plate.

The support portion may elastically support the guide plate in a direction opposite to a direction in which the cover holds the guide plate.

In this case, the cover is less likely to move in a direction in which the cover and the guide plate are connected.

The cover may include a recess that comes into contact with a facing surface of the guide plate, and the recess may have a size that allows the recess to slide on the facing surface along a direction of the sliding movement.

In this case, the cover can smoothly slide on the guide plate even during the sliding movement.

The engaged portion may be a shaft body including a head portion, the cover may include, at a position continuous with the engaging portion, an insertion portion through which the shaft body is inserted, and the engaging portion may be engaged with a lower surface of the head portion.

In this case, the cover is less likely to move in a direction in which the cover and the guide plate are connected.

The shaft body may be a screw, the pin block may include a screw hole corresponding to the screw, and a projection portion that comes into contact with the lower surface of the head portion of the screw inserted into the screw hole, and a height of the projection portion may be larger than a thickness of the engaging portion.

In this case, the cover is less likely to move in a direction in which the cover and the guide plate are connected.

The pin block may include a displacement restriction portion configured to restrict a displacement of the cover in the direction of the sliding movement in a state where the engaging portion is engaged with the engaged portion.

In this case, the cover is less likely to be displaced in the direction of the sliding movement.

### REFERENCE SIGNS LIST

5 Inspection device
9 IC package to be inspected
10 IC Inspection socket
12 Socket body
30 Pin block
32 Accommodation recess
36 Engaged portion
36a Screw
36b Screw hole
36c Projection portion
40 Guide plate
48 Guide surface
49 Positioning portion
50 Cover
52 Facing recess
53 First fixing portion
53c First engaging portion
54 Second fixing portion
54b Insertion portion
54d Second engaging portion
60 Contact probe array
70 Support portion
80 Displacement restriction portion

1. An IC inspection socket comprising:
a pin block including a contact probe array;
a guide plate configured to guide an IC package to be inspected to the contact probe array; and
a cover including an engaging portion to be engaged with the pin block, and configured to hold the guide plate by an engagement of the engaging portion,
wherein the pin block includes
a support portion configured to detachably support the guide plate, and
an engaged portion with which the engaging portion is engaged during a sliding movement of the cover on the guide plate supported by the support portion.

2. The IC inspection socket according to claim 1, wherein
the support portion elastically supports the guide plate in a direction opposite to a direction in which the cover holds the guide plate.

3. The IC inspection socket according to claim 1, wherein
the cover includes a recess that comes into contact with a facing surface of the guide plate, and
the recess has a size that allows the recess to slide on the facing surface along a direction of the sliding movement.

4. The IC inspection socket according to claim 1, wherein
the engaged portion is a shaft body including a head portion,
the cover includes, at a position continuous with the engaging portion, an insertion portion through which the shaft body is inserted, and
the engaging portion is engaged with a lower surface of the head portion.

5. The IC inspection socket according to claim 4, wherein
the shaft body is a screw,
the pin block includes
a screw hole corresponding to the screw, and
a projection portion that comes into contact with the lower surface of the head portion of the screw inserted into the screw hole, and
a height of the projection portion is larger than a thickness of the engaging portion.

6. The IC inspection socket according to claim 5, wherein
the pin block includes a displacement restriction portion configured to restrict a displacement of the cover in the direction of the sliding movement in a state where the engaging portion is engaged with the engaged portion.

7. The IC inspection socket according to claim 2, wherein
the cover includes a recess that comes into contact with a facing surface of the guide plate, and
the recess has a size that allows the recess to slide on the facing surface along a direction of the sliding movement.

8. The IC inspection socket according to claim 2, wherein
the engaged portion is a shaft body including a head portion,
the cover includes, at a position continuous with the engaging portion, an insertion portion through which the shaft body is inserted, and
the engaging portion is engaged with a lower surface of the head portion.

9. The IC inspection socket according to claim 3, wherein
the engaged portion is a shaft body including a head portion,
the cover includes, at a position continuous with the engaging portion, an insertion portion through which the shaft body is inserted, and
the engaging portion is engaged with a lower surface of the head portion.

10. The IC inspection socket according to claim 8, wherein
the shaft body is a screw,
the pin block includes
a screw hole corresponding to the screw, and
a projection portion that comes into contact with the lower surface of the head portion of the screw inserted into the screw hole, and
a height of the projection portion is larger than a thickness of the engaging portion.

11. The IC inspection socket according to claim 9, wherein
the shaft body is a screw,
the pin block includes
a screw hole corresponding to the screw, and
a projection portion that comes into contact with the lower surface of the head portion of the screw inserted into the screw hole, and
a height of the projection portion is larger than a thickness of the engaging portion.

12. The IC inspection socket according to claim 7, wherein
the pin block includes a displacement restriction portion configured to restrict a displacement of the cover in the direction of the sliding movement in a state where the engaging portion is engaged with the engaged portion.

13. The IC inspection socket according to claim 8, wherein
the pin block includes a displacement restriction portion configured to restrict a displacement of the cover in the direction of the sliding movement in a state where the engaging portion is engaged with the engaged portion.

14. The IC inspection socket according to claim 9, wherein
the pin block includes a displacement restriction portion configured to restrict a displacement of the cover in the direction of the sliding movement in a state where the engaging portion is engaged with the engaged portion.

15. The IC inspection socket according to claim 10, wherein
the pin block includes a displacement restriction portion configured to restrict a displacement of the cover in the direction of the sliding movement in a state where the engaging portion is engaged with the engaged portion.

16. The IC inspection socket according to claim 11, wherein
the pin block includes a displacement restriction portion configured to restrict a displacement of the cover in the direction of the sliding movement in a state where the engaging portion is engaged with the engaged portion.
